(19) United States
(12) Patent Application Publication
(10) Pub. No.: US 2018/0240920 A1
(43) Pub. Date: Aug. 23, 2018

(54) SOLAR CELL, METHOD FOR MANUFACTURING THE SAME, AND ELECTRICAL EQUIPMENT

(71) Applicant: BOE TECHNOLOGY GROUP CO., LTD., Beijing (CN)

(72) Inventor: Lizhong WANG, Beijing (CN)

(73) Assignee: BOE TECHNOLOGY GROUP CO., LTD., Beijing (CN)

(21) Appl. No.: 15/708,562

(22) Filed: Sep. 19, 2017

(30) Foreign Application Priority Data
Feb. 23, 2017 (CN) 201710100345.8

(51) Int. Cl. H01L 31/0352; H01L 31/18; H01L 31/0725; H01L 31/0336; H01L 31/0224

(52) U.S. Cl. CPC H01L 31/035227; H01L 31/1864; H01L 31/022425; H01L 31/0725; H01L 31/0336; H01L 31/18

(57) ABSTRACT

The present disclosure provides a solar cell, a method for manufacturing the same, and an electrical equipment. The solar cell comprises a first substrate and a second substrate arranged opposite to each other; and a plurality of PN junctions arranged between the first substrate and the second substrate, each of the plurality of PN junctions connecting the first substrate and the second substrate and comprising an inner core serving as a P electrode, and a coating layer serving as an N electrode and coating the inner core.

### CROSS-REFERENCE TO RELATED APPLICATION

This application claims priority to Chinese Patent Application No. 201710100345.8 filed on Feb. 23, 2017, which is incorporated herein by reference in its entirety.

### TECHNICAL FIELD

The present disclosure relates to the field of battery technology, and in particular to a solar cell, a method for manufacturing the same, and an electrical equipment.

### BACKGROUND

Crystalline silicon solar cells usually adopt a planar laminated structure formed of a P-type semiconductor and an N-type semiconductor. However, the solar cells adopting such structure also have problems such as slow charge carrier separation velocity, and long transfer distance, which results in easy recombination of photo-induced electron hole pairs and directly influences conversion efficiency of the solar cells.

### SUMMARY

An object of the present disclosure is to provide a technical solution capable of increasing the conversion efficiency of the solar cells.

On one hand, an embodiment of the present disclosure provides a solar cell, comprising:

a first substrate and a second substrate arranged opposite to each other; and

a plurality of PN junctions arranged between the first substrate and the second substrate, each of the plurality of PN junctions connecting the first substrate and the second substrate and comprising an inner core serving as a P electrode, and a coating layer serving as an N electrode and coating the inner core.

Optionally, the inner core is made of a material comprising zinc oxide, and the coating layer is made of a material comprising gallium nitride.

Optionally, each of the plurality of PN junctions has a shape of cylinder, and the cylinder has a nano-scale diameter.

Optionally, the second substrate serves as a light-absorbing surface of the solar cell, and both ends of each of the plurality of PN junctions are in direct contact with the first substrate and the second substrate, respectively;

the inner core is of a nanowire structure and substantially vertically arranged on the first substrate; and the inner core has an outer side surface, a first end in contact with the first substrate and a second end directed to and not in contact with the second substrate;

the coating layer comprises a first portion and a second portion, the first portion covers the outer side surface of the inner core, the second portion covers the second end of the inner core and is sandwiched between the second end of the inner core and the second substrate and in direct contact with the second substrate; and

the PN junctions are arranged at intervals, and the inner cores are arranged at intervals.

Optionally, the second substrate serves as a light-absorbing surface of the solar cell, and only the coating layer of each of the plurality of PN junctions is in contact with the second substrate.

Optionally, the first substrate comprises a gold film, and the inner core of each of the plurality of PN junctions is arranged on the gold film of the first substrate.

Optionally, the plurality of PN junctions are uniformly distributed between the first substrate and the second substrate.

On the other hand, an embodiment of the present disclosure further provides a method for manufacturing the solar cell, comprising:

depositing a P electrode material on a first substrate so as to form inner cores of a plurality of PN junctions;

coating the inner cores with an N electrode material so as to form coating layers of the plurality of PN junctions; and

arranging a second substrate opposite to the first substrate so that each of the plurality of PN junctions is connected to the first substrate and the second substrate.

Optionally, the depositing the P electrode material on the first substrate so as to form the inner cores of the plurality of PN junctions comprises:

depositing the P electrode material on the first substrate through a chemical vapor deposition process or a hydrothermal electrophoretic deposition process so as to form the inner cores of the plurality of PN junctions, wherein the P electrode material comprises zinc oxide.

Optionally, the depositing the P electrode material on the first substrate through the chemical vapor deposition process comprises:

sputtering a cocatalyst comprising gold on the first substrate so as to form a gold film on the first substrate; and

heating the first substrate at a temperature of 500-800 degrees Celsius for 0.5-1.5 hours by using zinc acetate or zinc nitrate as a raw material, and 50-150 sccm of gas mixture of argon and oxygen as a carrier gas, so as to form the inner cores deposited with zinc oxide on the gold film of the first substrate, wherein argon:oxygen=10:1.

Optically, the coating the inner cores with the N electrode material comprises:

fixing the N electrode material to the inner cores and coating the inner cores through a sintering process, wherein the N electrode material comprises gallium nitride.

Optionally, the fixing the N electrode material to the inner cores and the coating the inner cores through the sintering process comprise:

heating the first substrate formed with the inner cores on the gold film at a temperature of 700-900 degrees Celsius for 0.5-2 hours by using gallium oxide or gallium nitrate as a raw material, and 50-150 sccm of ammonia gas as a carrier gas such that the inner core on the gold film of the first substrate is coated with gallium nitride to obtain the coating layer.

Further, an embodiment of the present disclosure provides an electrical equipment comprising the solar cell described above.

### BRIEF DESCRIPTION OF THE DRAWINGS

FIG. 1 is a schematic view showing a structure of a solar cell in related art;

FIG. 2 is a schematic view showing a structure of a solar cell in an embodiment of the present disclosure; and

FIGS. 3A-3C are flow charts showing a method for manufacturing a solar cell in an embodiment of the present disclosure.

### DETAILED DESCRIPTION

In order to make the technical problems, the technical solutions and the advantages of the present disclosure more apparent, the present disclosure will be described hereinafter in a clear manner in conjunction with the drawings and embodiments.

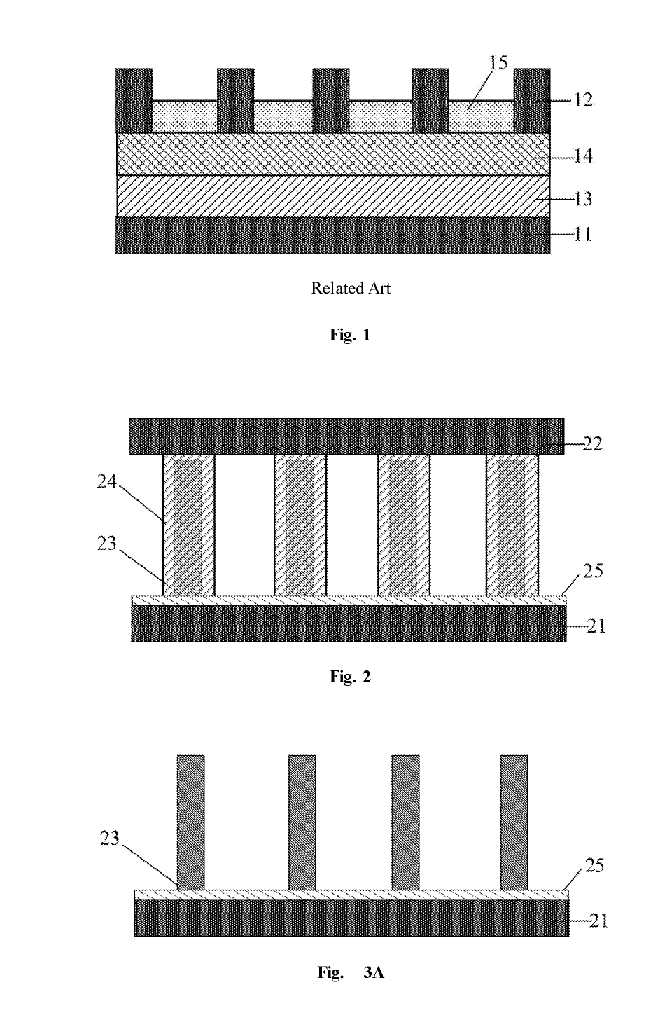

FIG. 1 is a schematic view showing a structure of a solar cell in related art. As shown in FIG. 1, a structure of a crystalline silicon solar cell mainly comprises: a front electrode 11, a back electrode 12, and a P-type semiconductor 13 (i.e., a P-type semiconductor electrode, hereinafter referred to as a P electrode) and an N-type semiconductor 14 (i.e., an N-type semiconductor electrode, hereinafter referred to as an N electrode) between the front electrode 11 and the back electrode 12. In order to reduce reflection of light from silicon wafer as a semiconductor, an anti-reflection layer 15 is additionally provided on a semiconductor surface so that the solar cell can absorb light energy fully.

However, as can be seen from FIG. 1, the solar cell in the related art adopting such structure of laminating the P-type semiconductor 13 and the N-type semiconductor 14 has problems such as slow charge carrier separation velocity, and long transfer distance, which results in easy recombination of photo-induced electron hole pairs and directly influences conversion efficiency of the solar cells. In the meanwhile, this design requires doping P-type ions and N-type ions of silicon crystals, increasing process difficulties. Moreover, the addition of the anti-reflection layer to the surface further increases manufacturing process and cost.

With regard to the above-described problems, an embodiment of the present disclosure provides the following technical solution.

On one hand, an embodiment of the present disclosure provides a solar cell, as shown in FIG. 2, comprising:

a first substrate 21 and a second substrate 22 arranged opposite to each other; and

a plurality of PN junctions arranged between the first substrate 21 and the second substrate 22, each of the plurality of PN junctions connecting the first substrate 21 and the second substrate 22 and comprising an inner core 23 serving as a P electrode, and a coating layer 24 serving as an N electrode and coating the inner core 23.

The PN junctions of the solar cell according to this embodiment have a structure of the N electrode surrounding the P electrode. Such structural design can increase the contacting area of the N electrode and the P electrode fully so that electrons and holes can be separated and transferred rapidly, increasing the utilization of the solar cell efficiently. Further, as compared with PN junctions having a laminated structure, the PN junction according to this embodiment can reduce the reflection area of light so that it is unnecessary to arrange an anti-reflection layer, resulting in reduction in manufacturing process and cost.

Hereinafter, the solar cell according to this embodiment will be introduced in detail in conjunction with practical application.

Schematically, an inner core of the solar cell according to this embodiment is made of a material comprising zinc oxide. The inner core can be formed through chemical vapor deposition/hydrothermal deposition. A coating layer of the solar cell according to this embodiment is made of a material comprising gallium nitride. The coating layer can be attached to the inner core by way of sintering.

Optionally, zinc oxide is a P-type semiconductor, with a band gap of about 3.37 eV at room temperature, and it is a typical direct wide band gap semiconductor. Zinc oxide is widely used in photoelectric, gas-sensitive, pressure sensitive, piezoelectric materials and other fields. In photoelectric conversion applications, excitation electrons have greater mobility in zinc oxide and contribute to increase photoelectric conversion efficiency, as compared with traditional thin film electrode. Therefore, as the P electrode of the solar cell, P-type impurities are not required to be doped through an ion implantation process. Gallium nitride not intended to be doped is of a N type in any cases, and it can be used for the N electrode without doping impurities through the ion implantation process

As can be seen, no ion implantation process is required during the manufacturing of the P electrode and the N electrode according to this embodiment. As compared with the related art, manufacturing process and cost are reduced. Of course, it has to be indicated that no application of ion implantation process to zinc oxide and gallium nitride according to this embodiment is based on the angle of saving manufacturing cost, rather than a necessary solution of the embodiment.

Further, in order to reduce the light reflection area of the PN junctions, the structure of each PN junction according to this embodiment is a cylinder on the whole, and the cylinder has a nano-scale diameter. With this structure, a region where the P electrode and the N electrode of the PN junction overlap extends in a vertical direction. Therefore, assuming that the region where the P electrode and the N electrode of the PN junction overlap according to this embodiment is the same as that in the related art, a traversing area taken is decreased dramatically. As can be known, light incident direction is roughly the same as the extending direction of the PN junctions, so that using the above-described design can reduce the reflection area of light from the PN junctions significantly. Therefore, assuming that the second substrate 22 serves as a light-absorbing surface of the solar cell, the anti-reflection layer may be not arranged.

Further, under nano-scale PN junctions, the inner core of the solar cell is of a nanowire structure. Zinc oxide with a nanowire structure can further speed up separation and transmission of electrons and holes and helps the solar cell to convert light energy into electric power.

Based on the above solution, when involving practical application, a plurality of PN junctions according to this embodiment can be uniformly distributed between the first substrate and the second substrate so as to uniformly support the first substrate and the second substrate, and can be used to maintain spacing between the first substrate and the second substrate so as to increase intension of the whole structure. Further, the uniform distribution of the PN junctions is more beneficial to absorb light energy fully so as to increase energy conversion efficiency of the cells.

Further, as an optional solution, assuming that the second substrate serves as a light-emitting surface, only the coating layer 24 of the PN junction according to this embodiment contacts the second substrate 22, and the inner core 23 does not contact the second substrate 22. Using such structural design can reduce electrons in the second substrate 22 to flow toward the inner core 23 and help to direction dividing motion of electrons and holes (i.e., the electrodes transfer in the coating layer 24, and the holes in the inner core 23) so as to be better for energy conversion efficiency.

Above is the exemplary introduction for the solar cell according to this embodiment. It has to be indicated that this embodiment is not limited to the PN junction being a cylinder. Other feasible solutions can realize the advantageous effects of the embodiment as long as the PN junction is of a structure in which the coating layer coating the inner core, and shall fall into the protection scope of the present disclosure.

Therefore, as compared with the related art, this embodiment has the following advantages:

1) the structure of PN junctions speeds up the separation of electrons and holes, and increases the utilization of solar cells;

2) the material of PN junctions does not need to use ion implantation process so that manufacturing process is reduced; and

3) the structure of PN junctions decreases the reflectivity of light, and it is not required to arrange an anti-reflection layer on the light-absorbing surface to reduce manufacturing cost.

### Embodiment 1

On the other hand, another embodiment of the present disclosure further provides a method for manufacturing a solar cell, comprising:

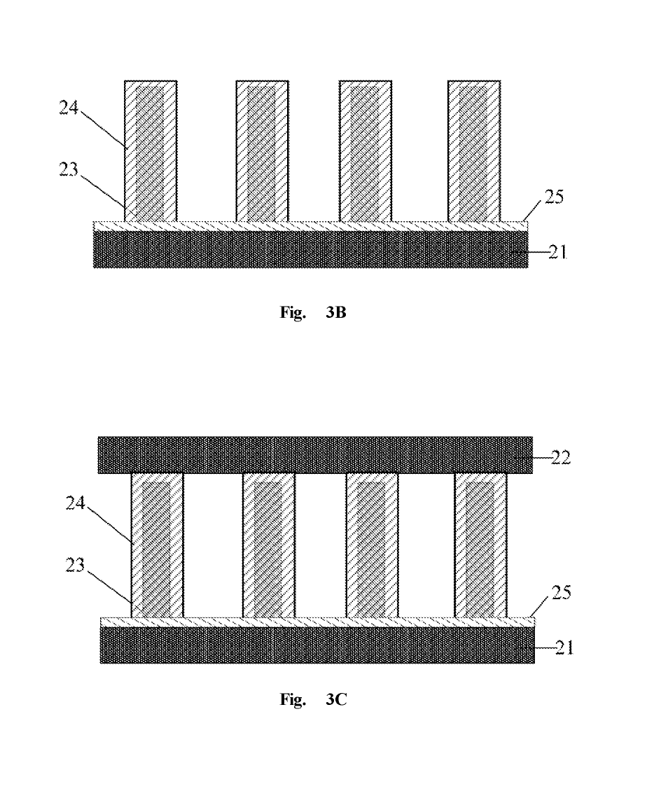

Step 31: as shown in FIG. 3A, depositing a P electrode material on first substrate 21 so as to form inner cores 23 of a plurality of PN junctions;

Step 32: as shown in FIG. 3B, coating the inner cores 23 with an N electrode material so as to form coating layers 24 of the plurality of PN junctions; and

Step 33: as shown in FIG. 3C, arranging second substrate 22 opposite to first substrate 21 so that each of the PN junctions is connected to the first substrate and the second substrate.

Therefore, the method for manufacturing the solar cell in the present disclosure according to this embodiment can realize the same technical effect as the solar cell according to the present disclosure.

Further, it has to be indicated that, in practical application, the solar cell according to this embodiment may be further provided with wirings or other components. Since the solution of this embodiment does not relate to these improvements, other related structures will not be stated here again. However, those skilled in the art, according to common knowledge, shall envisage the solar cell according to this embodiment further comprises other related components as stated above.

Hereinafter, a method for manufacturing PN junctions according to this embodiment will be introduced in detail in conjunction with practical application.

With regard to the method for manufacturing the P electrodes in this embodiment, zinc oxide may be deposited on the first substrate so as to form the inner cores of a plurality of PN junctions through a chemical vapor deposition process or a hydrothermal electrophoretic deposition process.

To take the chemical vapor deposition process as an example, the step 31 according to this embodiment comprises:

Step 311: sputtering a cocatalyst comprising gold on the first substrate so as to form a gold film 25 on the first substrate; and

Step 312: heating the first substrate at a temperature of 650 degrees Celsius for 1 hour by using zinc acetate or zinc nitrate as a raw material, and 100 sccm (sccm is a unit of volume flowrate, representing milliliters per minute under standard condition) of gas mixture of argon and oxygen as a carrier gas, wherein argon:oxygen=10:1. During the heating, because of the action of cocatalyst, zinc acetate or zinc nitrate is converted into zinc oxide, and inner cores with a nanowire structure are gradually deposited on gold film 25 of the first substrate in a longitudinal direction.

It has to be indicated that related method for manufacturing the P electrode is to deposit a layer of monocrystalline silicon materials firstly, and then dope the monocrystalline silicon materials through an ion implantation process so that the monocrystalline silicon materials are converted into polycrystalline silicon materials as a P electrode. According to this embodiment, zinc oxide can be directly deposited by using the chemical vapor deposition process. Since zinc oxide is a polycrystalline silicon material, it is not required to use the ion implantation process.

Further, since the hydrothermal electrophoretic deposition process is a related art, it will be not stated again in the present disclosure. However, it has to be indicated that, similar to the chemical vapor deposition process, zinc oxide can also be directly deposited by using the hydrothermal electrophoretic deposition process, without using the ion implantation process.

With respect to the method for manufacturing the N electrode, according to this embodiment, gallium nitride can be fixed to the inner cores and coat the inner cores through a sintering process so as to form a coating layer.

As an example for introducing the sintering process in this embodiment, the first substrate formed with the inner cores on the gold film is heated at a temperature of 800 degrees Celsius for 1.0 hour by using gallium oxide or gallium nitrate as a raw material, and 100 sccm of ammonia gas as a carrier gas. During the heating, gallium oxide or gallium nitrate is fixed to the inner core through ammonia gas and converted into gallium nitride, thereby obtaining the coating layer of the PN junction.

### Embodiments 2-9

Methods used in the following embodiments are the same as that in embodiment 1, except different process parameters below.

| | Method for manufacturing P electrode | | | Method for manufacturing N electrode | | |
|---|---|---|---|---|---|---|
| | (chemical vapor deposition process) | | | (sintering process) | | |
| | | Temperature | | | Temperature | |
| | | for heating | Time for | | for heating | Time for |
| | | first substrate | heating first | | first substrate | heating first |
| | Gas mixture | (degrees | substrate | Ammonia | (degrees | substrate |
| Embodiments | (sccm) | Celsius) | (h) | gas (sccm) | Celsius) | (h) |
| 2 | 50 | 500 | 0.5 | 50 | 700 | 0.5 |
| 3 | 150 | 500 | 0.5 | 150 | 700 | 0.5 |
| 4 | 50 | 800 | 0.5 | 50 | 900 | 0.5 |
| 5 | 150 | 800 | 0.5 | 150 | 900 | 0.5 |
| 6 | 50 | 500 | 1.5 | 50 | 700 | 2.0 |
| 7 | 150 | 500 | 1.5 | 150 | 700 | 2.0 |
| 8 | 50 | 800 | 1.5 | 50 | 900 | 2.0 |
| 9 | 150 | 800 | 1.5 | 150 | 900 | 2.0 |

It is clear that the manufacturing method according to the embodiments of the present disclosure is capable of not using the ion implantation process for manufacturing the PN junctions. Therefore, manufacturing process and cost can be reduced, which has notable significance in mass manufacturing the solar cells.

Above is the introduction for the manufacturing method of the embodiments of the present disclosure, in which, the methods for forming the inner core and the coating layer described above are provided only for exemplary introduction, but not limited to the protection scope of the disclosure.

Further, an embodiment of the present disclosure further provides an electrical equipment comprising the solar cell according to the present disclosure. Based on the structure design of the solar cell, the electrical equipment according to the present disclosure can store electric power in a more efficient manner under light irradiation and increase practicability of the solar cell effectively.

It has to be indicated that the present disclosure does not limit specific expression forms of the electrical equipment in practical application. For example, the electrical equipment according to the embodiment may be a cellphone, a PAD, a calculator, a water heater or the like. All electrical equipments mainly using the solar cell provided in the present disclosure shall fall into the protection scope of the present disclosure.

To sum up, at least one embodiment according to the present disclosure has the following advantageous effects.

The PN junctions of the solar cell according to the present disclosure have a structure of the N electrode surrounding the P electrode. Such structural design can increase the contacting area of the N electrode and the P electrode fully so that electrons and holes can be separated and transferred rapidly, increasing the utilization of the solar cell efficiently. Further, as compared with PN junctions having a laminated structure, the PN junction according to this embodiment can reduce the reflection area of light so that it is not required to arrange an anti-reflection layer, resulting in reduction in manufacturing process and cost. Further, the electrical equipment using the solar cell according to the present disclosure can store electric power in a more efficient manner under light irradiation, increase practicability of the solar cell significantly and help to popularity of the solar cell.

The foregoing is a preferred embodiment of the present disclosure. It should be noted that those of ordinary skill in the art may further make a number of improvements and modifications without departing from the principles of the present disclosure, which improvements and modifications should also be deemed to be within the scope of the present disclosure.

What is claimed is:

1. A solar cell, comprising:
a first substrate and a second substrate arranged opposite to each other; and
a plurality of PN junctions arranged between the first substrate and the second substrate, each of the plurality of PN junctions connecting the first substrate and the second substrate and comprising an inner core serving as a P electrode, and a coating layer serving as an N electrode and coating the inner core.

2. The solar cell according to claim 1, wherein
the inner core is made of a material comprising zinc oxide, and the coating layer is made of a material comprising gallium nitride.

3. The solar cell according to claim 1, wherein
each of the plurality of PN junctions has a shape of cylinder, and the cylinder has a nano-scale diameter.

4. The solar cell according to claim 1, wherein
the second substrate serves as a light-absorbing surface of the solar cell, and both ends of each of the plurality of PN junctions are in direct contact with the first substrate and the second substrate, respectively;
the inner core is of a nanowire structure and substantially vertically arranged on the first substrate; and the inner core has an outer side surface, a first end in contact with the first substrate and a second end directed to and not in contact with the second substrate;
the coating layer comprises a first portion and a second portion, the first portion covers the outer side surface of the inner core, the second portion covers the second end of the inner core and is sandwiched between the second end of the inner core and the second substrate and in direct contact with the second substrate; and
the PN junctions are arranged at intervals, and the inner cores are arranged at intervals.

5. The solar cell according to claim 1, wherein
the second substrate serves as a light-absorbing surface of the solar cell, and only the coating layer of each of the plurality of PN junctions is in contact with the second substrate.

6. The solar cell according to claim 1, wherein
the first substrate comprises a gold film, and the inner core of each of the plurality of PN junctions is arranged on the gold film of the first substrate.

7. The solar cell according to claim 1, wherein
the plurality of PN junctions are uniformly distributed between the first substrate and the second substrate.

8. A method for manufacturing the solar cell according to claim 1, comprising:
depositing a P electrode material on a first substrate so as to form inner cores of a plurality of PN junctions;
coating the inner cores with an N electrode material so as to form coating layers of the plurality of PN junctions; and
arranging a second substrate opposite to the first substrate so that each of the plurality of PN junctions is connected to the first substrate and the second substrate.

9. The method according to claim 8, wherein
the depositing the P electrode material on the first substrate so as to form the inner cores of the plurality of PN junctions comprises:
depositing the P electrode material on the first substrate through a chemical vapor deposition process or a hydrothermal electrophoretic deposition process so as to form the inner cores of the plurality of PN junctions, wherein the P electrode material comprises zinc oxide.

10. The method according to claim 9, wherein
the depositing the P electrode material on the first substrate through the chemical vapor deposition process comprises:
sputtering a cocatalyst comprising gold on the first substrate so as to form a gold film on the first substrate; and
heating the first substrate at a temperature of 500-800 degrees Celsius for 0.5-1.5 hours by using zinc acetate or zinc nitrate as a raw material, and 50-150 sccm of gas mixture of argon and oxygen as a carrier gas, so as to form the inner cores deposited with zinc oxide on the gold film of the first substrate, wherein argon:oxygen=10:1.

11. The method according to claim 8, wherein
the coating the inner cores with the N electrode material comprises:
fixing the N electrode material to the inner cores and coating the inner cores through a sintering process, wherein the N electrode material comprises gallium nitride.

12. The method according to claim 11, wherein
the fixing the N electrode material to the inner cores and the coating the inner cores through the sintering process comprise:
heating the first substrate formed with the inner cores on the gold film at a temperature of 700-900 degrees Celsius for 0.5-2 hours by using gallium oxide or gallium nitrate as a raw material, and 50-150 sccm of ammonia gas as a carrier gas such that the inner core on the gold film of the first substrate is coated with gallium nitride to obtain the coating layer.

13. The method according to claim 8, wherein
each of the plurality of PN junctions has a shape of cylinder, and the cylinder has a nano-scale diameter.

14. The method according to claim 8, wherein
the second substrate serves as a light-absorbing surface of the solar cell, and both ends of each of the plurality of PN junctions are in direct contact with the first substrate and the second substrate, respectively;
the inner core is of a nanowire structure and substantially vertically arranged on the first substrate; and the inner core has an outer side surface, a first end in contact with the first substrate and a second end directed to and not in contact with the second substrate;
the coating layer comprises a first portion and a second portion, the first portion covers the outer side surface of the inner core, the second portion covers the second end of the inner core and is sandwiched between the second end of the inner core and the second substrate and in direct contact with the second substrate; and
the PN junctions are arranged at intervals, and the inner cores are arranged at intervals.

15. The method according to claim 8, wherein
the plurality of PN junctions are uniformly distributed between the first substrate and the second substrate.

16. An electrical equipment comprising the solar cell according to claim 1.

17. The electrical equipment according to claim 16, wherein
the inner core is made of a material comprising zinc oxide, and the coating layer is made of a material comprising gallium nitride.

18. The electrical equipment according to claim 16, wherein
each of the plurality of PN junctions has a shape of cylinder, and the cylinder has a nano-scale diameter.

19. The electrical equipment according to claim 16, wherein
the second substrate serves as a light-absorbing surface of the solar cell, and both ends of each of the plurality of PN junctions are in direct contact with the first substrate and the second substrate, respectively;
the inner core is of a nanowire structure and substantially vertically arranged on the first substrate; and the inner core has an outer side surface, a first end in contact with the first substrate and a second end directed to and not in contact with the second substrate;
the coating layer comprises a first portion and a second portion, the first portion covers the outer side surface of the inner core, the second portion covers the second end of the inner core and is sandwiched between the second end of the inner core and the second substrate and in direct contact with the second substrate; and
the PN junctions are arranged at intervals, and the inner cores are arranged at intervals.

20. The electrical equipment according to claim 16, wherein
the plurality of PN junctions are uniformly distributed between the first substrate and the second substrate.
